(19) United States
(12) Patent Application Publication
(10) Pub. No.: US 2021/0367438 A1
(43) Pub. Date: Nov. 25, 2021

(54) BATTERY ADAPTER

(71) Applicant: Federal Bureau of Investigation, Washington, DC (US)

(72) Inventors: Bradley A. Dauberman, Shrewsbury, PA (US); Michael B. Lochner, Occoquan, VA (US); Michael A. Malone, Manassas, VA (US)

(73) Assignee: Federal Bureau of Investigation, Washington, DC (US)

(21) Appl. No.: 17/036,431

(22) Filed: Sep. 29, 2020

Related U.S. Application Data
(60) Provisional application No. 62/927,955, filed on Oct. 30, 2019.

(51) Int. Cl. H02J 7/00; H05K 7/14; H01R 33/94; H01R 33/945; H01R 13/717

(52) U.S. Cl. CPC H02J 7/0045; H02J 7/0049; H02J 7/00711; H01R 13/7175; H01R 33/94; H01R 33/945; H05K 7/1427

(57) ABSTRACT

An adapter that is a lightweight and portable passive device with circuitry that converts voltage and current from a first type of battery into usable voltage and current for a second type of battery. The second type of battery is the battery that powers a USB device, such as a cellular telephone. The first type of battery may be any type of battery, such as a radio battery. The adapter is pocket-sized and robust for portability and long-term use.

This application claims priority to Provisional Patent Application 62/927,955 filed on Oct. 30, 2019, the contents of which are hereby incorporated by reference in their entirety.

### FIELD

The present subject matter relates generally to adapters. In particular, the present subject matter relates to a device for converting a radio battery into an external battery and charger for any USB device.

### BACKGROUND

When first responders are working in the field, they rely on both cell phones and batteries to support their efforts. Often, spare radio batteries are readily available from a mobile command center, while cell phones require special chargers and access to a power source to recharge. The present subject matter relates to an adapter to allow spare radio or other types of batteries to be used to use and charge cell phones with little to no down time.

### BRIEF DESCRIPTION OF THE DRAWINGS

A description of the present subject matter including various embodiments thereof is presented with reference to the accompanying drawings, the description not meaning to be considered limiting in any matter, wherein:

FIG. 1 illustrates an exemplary embodiment of a battery adapter associated with a radio battery;

FIG. 2 illustrates multiple units of an exemplary embodiment of a battery adapter with each unit having a battery inserted;

FIG. 3 illustrates a perspective view of an exemplary battery adapter with a form factor to receive a radio battery;

FIG. 4 illustrates a side view of an exemplary embodiment of a battery adapter with a form factor to receive a radio battery;

FIGS. 5A-5C illustrate an exemplary embodiment of a battery adapter in various stages of assembly;

FIGS. 6A-6C illustrate an exemplary embodiment of battery adapter circuitry in various stages of assembly;

FIG. 7 illustrates another exemplary embodiment of battery adapter circuitry in a stage of assembly;

FIG. 8 illustrates an exemplary embodiment of battery adapter circuitry;

FIG. 9 is a graph showing charging curves for an exemplary embodiment of a battery adapter;

FIG. 10 shows various charging curves versus time: curve A is battery (radio; battery inserted into the battery adapter) voltage versus time, curve B is phone charged percentage versus time, and curve C is battery current versus time; and

FIG. 11 is a table showing time to charge and volts, phone charge, and battery current at various times and is the underlying data for the curves in FIG. 10.

### DETAILED DESCRIPTION

Throughout the discussion below, use of the terms “about” and “approximately” are used to indicate engineering tolerances which would be well understood by a person of ordinary skill in the art for any particular application or embodiment.

The adapter provided below and shown and described in the drawings is a lightweight and portable passive device with circuitry that converts voltage and current from a first type of battery into usable voltage and current for a second type of battery. The second type of battery is the battery that powers a USB device, such as a cellular telephone. The first type of battery may be any type of battery, but in one embodiment is a radio battery.

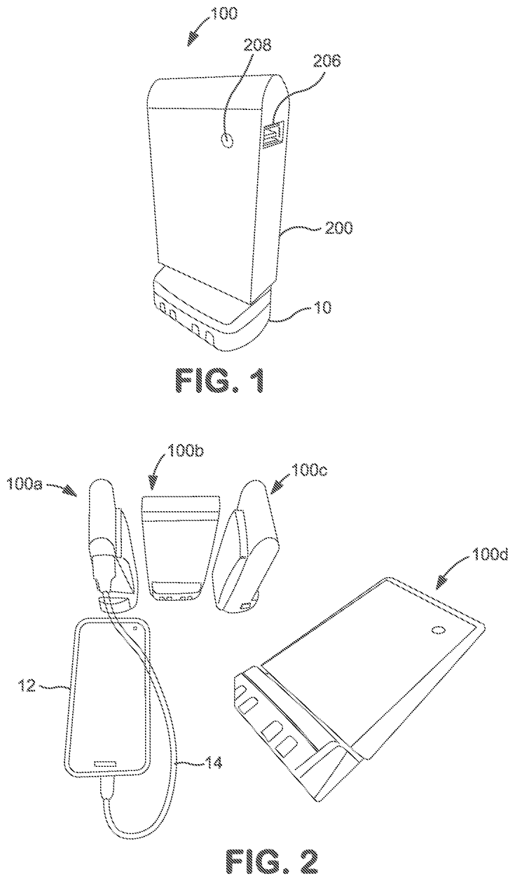

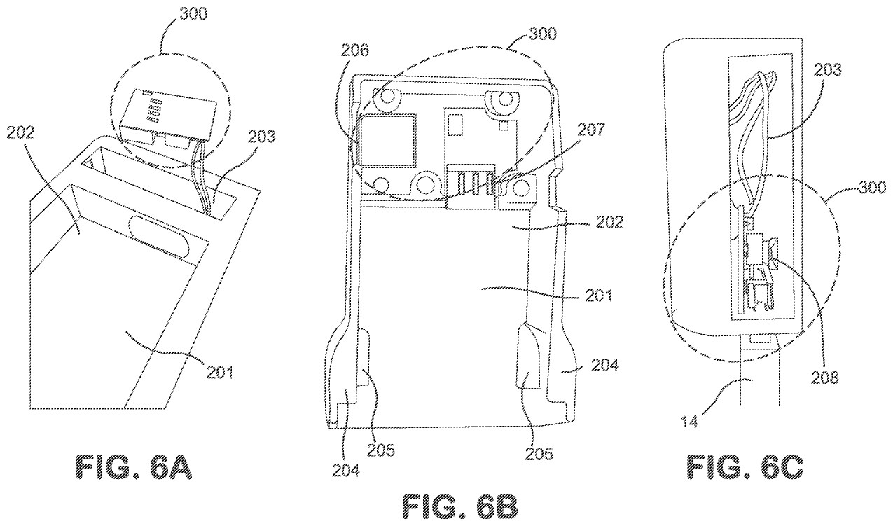

FIG. 1 illustrates an exemplary embodiment of a battery adapter 100 associated with a battery 10. In the exemplary embodiment of FIG. 1, adapter 100 is a lightweight and portable passive device with circuitry 300 (see, e.g., FIGS. 6A-8) that converts voltage and current from a first type of battery 10 into usable voltage and current for a second type of battery (not shown). The first type of battery 10 may be any type of battery, but in one embodiment is a radio battery. In some embodiments, the first type of battery 10 is a Motorola APX battery. It is well known that many first responders use Motorola APX 7000 series radios and carry spare batteries for those radios. In the exemplary embodiment shown the second type of battery is a battery that powers a USB device, such as a cellular telephone. To maximize the portability of the adapter, in some embodiments, the size of the adapter is similar to that of a deck of playing cards. In some embodiments, the adapter may be about 2.5 inches wide and 3.5 inches long. In other embodiments, these dimensions may vary. In some embodiments, the adapter may be sized and dimensioned to fit comfortably within a pocket of an article of clothing, such as a standard pants or jacket pocket, a cargo-type pocket, or a pocket on a tactical vest or pants.

FIG. 2 illustrates multiple units of an exemplary embodiment of a battery adapter 100 with each unit having a battery 10 inserted. As shown in FIG. 2, a cellular telephone 12 connects to battery adapter 100a via a cord 14 connecting to a port 206. In battery adapter 100a, cord 14 is a USB male Type A to male to Type mini-A cord, but need not be. Other cords known to those of skill in the cellular phone and portable electronic device arts can be used without departing from the scope of the present subject matter. The other embodiments shown (100b/100c/100d) illustrate front, side, and top views respectively of an exemplary battery adapter with a battery inserted.

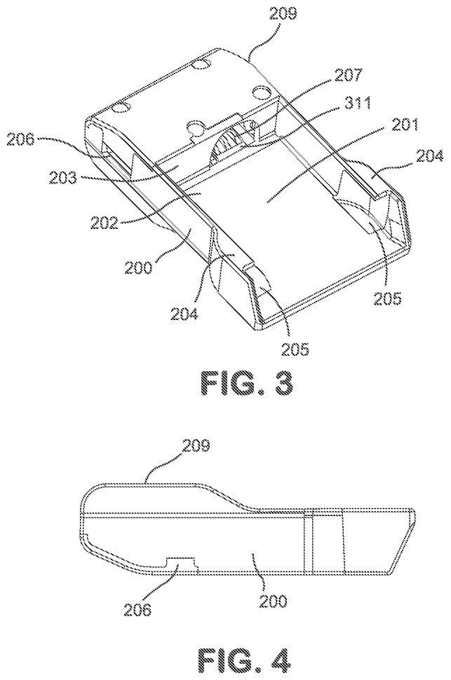

FIG. 3 illustrates a perspective view of an exemplary battery adapter 100 with a form factor to receive a radio battery 10, and FIG. 4 illustrates a side view of an exemplary embodiment of a battery adapter 100 with a form factor to receive a radio battery 10. The adapter 100 is intended to be portable and lightweight. In the exemplary embodiments shown in FIGS. 3 and 4, battery adapter 100 includes a housing 200 configured to receive the first type of battery 10. In some embodiments, housing 200 is made at least in part of a lightweight plastic such as acrylic styrene acrylonitrile (ASA) or polylactic acid (PLA). In some embodiment, housing 200 is made of a composite material, such as an acrylonitrile butadiene styrene (ABS) polycarbonate blend. In some embodiments, housing 200 is made at least in part from a material that can be injection molded. In some embodiments, housing 200 is made at least in part from a material that can be made using additive printing. In some embodiments, the material of the housing is selected to be able to withstand long-term storage in a hot environment, such as a car in the sun, without warping.

In some embodiments, housing 200 includes at least one port 206 (which can, but need not be a USB port), and an indicator 208. In certain embodiments indicator 208 is a light, and in some embodiments the light is an LED. In the embodiment shown, port 206 is in the side of housing 200, but can be located elsewhere in the housing 200, and there can be more than one port 206. In the exemplary embodiment of FIGS. 3 and 4, housing 200 further includes a retaining mechanism 204, such as a slot, hole, or geometric configuration for an engineering fit, to securely hold adapter 100 to the first type of battery when the battery 10 is inserted into housing 200. In some embodiments, housing 200 is wearable and includes a wearable attachment 205 such as a loop or clip, for example, so that the adapter 100 may be worn, such as on a belt or attached to an article of clothing or equipment, such as a back pack or holster, either directly such as by threading a part of the article or equipment through the loop or clip, or using a connecting device, such as a carabiner.

In some embodiments, the housing has a cavity 201 configured to receive the first type of battery 10. In the embodiment shown, a compartment 203 is disposed on a cavity first end 202, with compartment 203 configured to hold circuitry 300 (see, e.g., FIGS. 6A-8) under cover 209, which in certain embodiments is removable. In the exemplary embodiment shown in FIGS. 3 and 4, compartment 203 includes one or more connectors 207 configured to connect circuitry 300 with a battery 10. In the embodiment shown connectors 207 are flat, while in other embodiments the connectors 207 are pins. In still other exemplary embodiments, the connectors 207 are a combination of flat and pin type connectors 207.

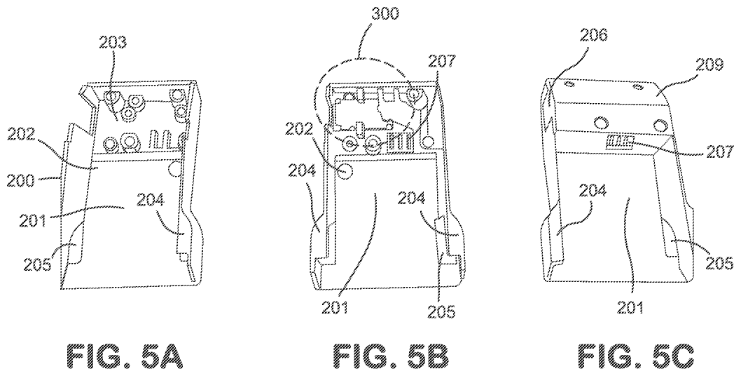

FIGS. 5A-5C illustrate an exemplary embodiment of a battery adapter 100 in various stages of assembly. FIG. 5A illustrates an exemplary housing 200 and cavity 201 having a wearable attachment 205. A compartment 203 is disposed in a first end 202 of the cavity 201, with no cover 209 or circuitry 300 installed. In FIG. 5B, circuitry 300 is partially installed and is connected to flat connectors 207, and is shown with no cover 209 installed on the housing 200, and FIG. 5C illustrates an exemplary housing 200 with a cover 209 installed.

FIGS. 6A-6C illustrate an exemplary embodiment of battery adapter circuitry 300 in various stages of assembly. FIG. 6A illustrates a front view of an exemplary embodiment of a battery adapter 100 with a cover 209 of the battery adapter 100 removed and an embodiment of a circuitry 300 associated with the battery adapter 100 partially removed. FIG. 6B illustrates an exemplary embodiment of circuitry 300 and associated electrical connectors 207 and ports 206 used and exemplary battery adapter 100, and FIG. 6C illustrates a top view of an exemplary embodiment of a battery adapter 100 showing a circuit board 301 including a USB Type A port 206 and electrical connectors 207 with a USB cord 14 inserted into the USB Type A port. The embodiment of FIG. 6C further includes an indicator 208, such as an LED, that is lighted when the first type of battery 10 is successfully inserted into the adapter 100 and is providing a charge. Since the adapter 100 is a passive device, an indicator 208 may only light up when a charge is provided by an external device (not shown). In some embodiments, the indicator 208 may change color when the device is fully charged.

In the exemplary embodiments of FIGS. 6A-6C, circuitry 300 is configured to regulate the voltage and current from the first type of battery 10 to the second type of battery (not shown) on the USB device. The circuitry 300 is disposed in a compartment 203 of the housing 200 adjacent the cavity first end 202. The exemplary circuitry 300 includes a circuit board 301 and is configured to provide a voltage to a number of connectors 207 on a port 206, that can but need not be a USB port, that is in electrical connection with the circuitry 300 and is disposed in the compartment 203 such that the port 206 extends from the circuit board 301 and though the housing 200. In the exemplary embodiment shown, port 206, thus, can provide a charge to an external device via a cable 14. In some embodiments, the USB port 206 includes connectors 207 configured to transmit data. In some embodiments with data connectors 207 on the USB port, those data connectors 207 are provided a voltage so that the adapter 100 may charge a USB device that requires a data connection to allow the USB battery to receive a charge. For example, some brands of smart phones require a voltage on the data connectors 207 for charging while other brands do not. To be able to use the adapter 100 with the maximum number of types of USB devices, in some embodiments, the data connectors 207 are provided a voltage.

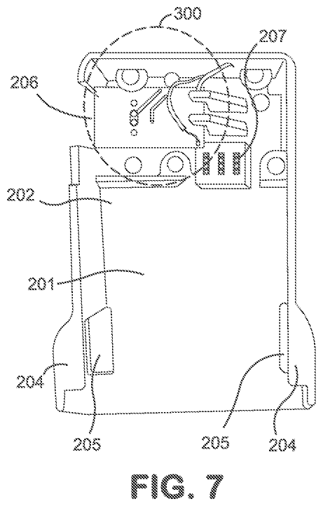

To transfer the voltage and current from the first type of battery to the port 206 and, ultimately, to the USB device battery, in some embodiments the electrical connectors 207 are disposed at cavity first end 202 and in electrical connection with the circuitry 300. In some embodiments, the electrical connectors 207 are mounted on a connector block 311. The electrical connectors 207 extend from the interior of the cavity 201 and into the compartment 203 to create a bridge between the circuitry 300 and the interior of the cavity 201. The electrical connectors 207 are positioned to align with and form an electrical connection with the battery 10 when the battery 10 is inserted into the adapter 100. In some embodiments, the electrical connectors 207 are flat connectors to increase the surface area of available connection to the battery 10 so that the positioning of the electrical connectors 207 on the housing 200 need not be precise. Furthermore, the flat-type connectors 207 are more robust than some other types of electrical connectors and can withstand multiple cycles of insertion and removal of the first type of battery 10, even if those insertions are done rapidly. Other embodiments, such as the exemplary embodiment in FIG. 7, use pin connectors 207, or a combination of pin and flat connectors 207.

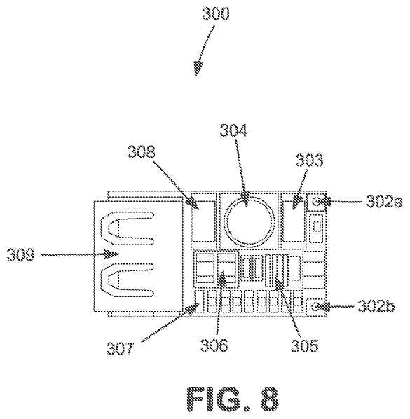

FIG. 8 illustrates an exemplary embodiment of battery adapter circuitry 300. In the embodiment shown, circuitry 300 includes positive input terminal 302a and negative input terminal 302b, with positive input terminal configured to accept an input voltage of between approximately 6-24 volts. Input terminal 302a electrically connects with input reverse polarity protection diode 303 to protect against connecting the input terminals to the wrong polarity input voltage. Circuitry 300 also includes at least one inductor 304, which in certain embodiments is an ultra-low internal resistance copper inductor. Input terminals 302a and 302b also connect to a rectification circuit 305, which in certain embodiments is a high efficiency synchronous rectification integrated circuit. This rectifier enables circuitry 300 to accept an alternating current power input and convert it into a direct current power input. Without being bound by any particular theory of operation, in at least one exemplary embodiment inventors consider rectification circuit 305 to function at least in part as synchronous step-down converter. In this exemplary embodiment circuit 305 includes a switching regulator configured to create voltage pulses.

The exemplary circuitry 300 shown also includes at least one capacitor 306, which in certain embodiments is a solid state high capacity multi-layer ceramic capacitor. Without being bound by any particular theory of operation, in at least one exemplary embodiment at least one of capacitors 306 is configured to smooth the voltage pulses from inductor 304 to create and maintain a DC output voltage. In certain embodiments, at least one capacitor 306 is configured to maintain an input DC voltage level, which in certain exemplary embodiments helps maintain a steady current in embodiments having a discontinuous voltage regulator output.

Exemplary circuitry 300 also includes an output voltage indicator 307, which in certain embodiments is configured to light up when an input voltage is detected at input terminals 302a and 302b. In certain embodiments, voltage indicator 307 is configured to change color when an attached device (not shown) is fully charged. The exemplary circuitry 300 shown also includes a transient voltage protector 308, which in the embodiment shown is a 300 watt transient voltage suppression (TVS) tube. Other watt values can be used, as can other transient voltage protectors known to those of skill in the art. Circuitry 300 also includes an output 309 electrically connected to the circuitry 300 and configured to deliver power to a phone connector (not shown). In the exemplary embodiment shown, output 309 is a USB connector configured to handle up to approximately 5.1 volts and 3 amps, enabling it to power most commercially available cell phones. These voltage and current values are exemplary only, as other values can be used without departing from the scope of the disclosed subject matter.

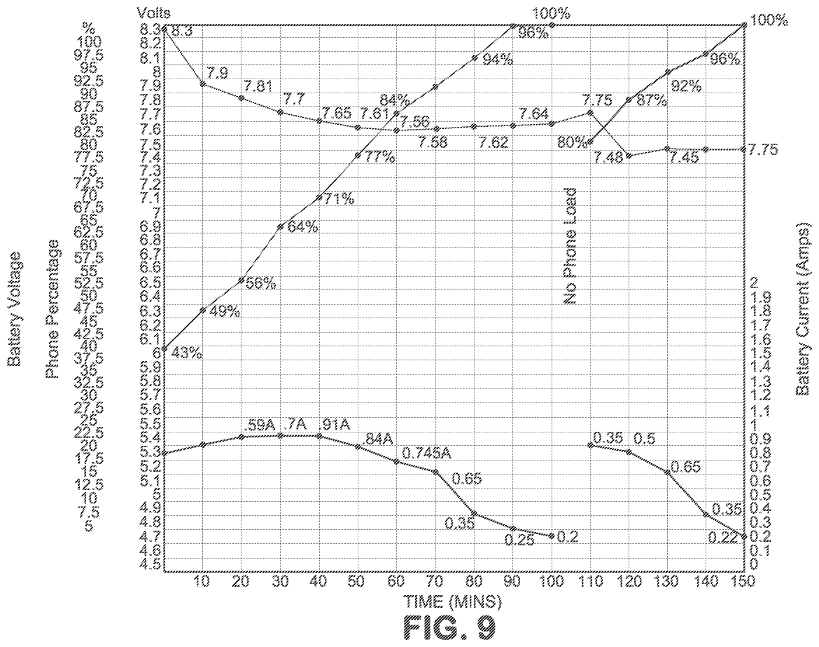

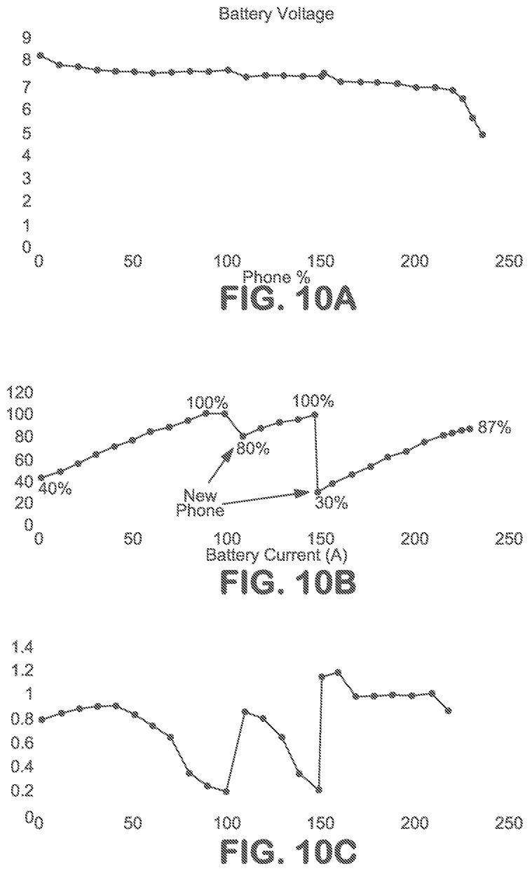

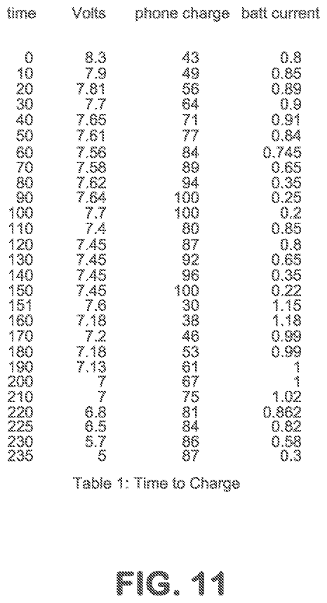

In some embodiments, when the adapter is fitted with a charged first type of battery 10, the adapter-battery combination may be used as an external battery so that the USB device may be used immediately and not only when the USB device battery has a sufficient charge. FIGS. 9-11 illustrate exemplary electrical characteristics of a charging cycle of a device charged by a battery adapter 100. FIG. 9 is a graph showing charging curves for an exemplary embodiment of a battery adapter. FIG. 10 shows various charging curves versus time: curve A is battery (radio; battery inserted into the battery adapter) voltage versus time, curve B is phone charged percentage versus time, and curve C is battery current versus time. FIG. 11 is a table showing time to charge and volts, phone charge, and battery current at various times and is the underlying data for the curves in FIG. 10.

### CONCLUSION

It will be understood that many additional changes in the details, materials, steps and arrangement of parts, which have been herein described and illustrated to explain the nature of the subject matter, may be made by those skilled in the art within the principle and scope of the invention as expressed in the appended claims. The steps of the methods described above may be performed in any order unless the order is restricted in the discussion. Any element of any embodiment may be used in any other embodiment and/or substituted for an element of any other embodiment unless specifically restricted in the discussion.

What is claimed is:

1. An adapter for powering a USB device, the adapter comprising:
a housing including a cavity configured to receive a battery in an interior of the cavity;
circuitry disposed in a compartment of the housing adjacent a first end of the cavity;
a port in electrical connection with the circuitry and disposed in the compartment such that the port extends from the circuitry and though the housing, and
electrical connectors disposed at the first end of the cavity and in electrical connection with the circuitry, wherein the electrical connectors create a bridge between the circuitry and the interior of the cavity, and wherein the electrical connectors are positioned to align with and form an electrical connection with the battery when the battery is inserted into the adapter,
wherein the port is configured to receive a USB connector, and
wherein the circuitry is configured to provide a voltage to a data connector on the port.

2. The adapter of claim 1, wherein the electrical connectors are flat-type connectors.

3. The adapter of claim 1, wherein the circuitry is configured to regulate a voltage from the battery to the port.

4. The adapter of claim 1, wherein the circuitry is configured to regulate a current from the battery to the port.

5. The adapter of claim 1, wherein the cavity has a form factor configured to receive a radio battery.

6. The adapter of claim 1, wherein the USB device is a cellular telephone.

7. The adapter of claim 1, wherein the adapter is portable.

8. The adapter of claim 7, wherein the adapter is configured to be carried in a pocket of an article of clothing.

9. The adapter of claim 7, wherein the housing includes a mechanism to make the adapter wearable.

10. The adapter of claim 1, wherein the housing includes a retainer configured to securely hold the battery in position when the battery is fully inserted.

11. The adapter of claim 10, wherein the retainer is formed from a contoured geometry of a side of the housing.

12. The adapter of claim 10, wherein the retainer is part of an engineering fit mechanism configured to mate with a movable flange on the battery.

13. The adapter of claim 1, wherein the circuitry includes a light configured to indicate when the battery is providing a charge to the USB device.

14. The adapter of claim 13, wherein the light is an LED light.

15. The adapter of claim 1, wherein the circuitry includes a circuit board.

16. The adapter of claim 15, wherein the port is integrated into the circuit board.

17. The adapter of claim 1, wherein the housing includes a main body, a connector block to support the electrical connectors, and a removable cover for the compartment.

18. The adapter of claim 1, wherein the housing is made of a lightweight plastic.

19. The adapter of claim 1, wherein the housing is made of a material used in additive printing.

20. The adapter of claim 1, wherein the housing is made of a material used in injection molding.
